(19) United States
(12) Patent Application Publication
(10) Pub. No.: US 2026/0011512 A1
(43) Pub. Date: Jan. 8, 2026

(54) Power Switching Device with Self Diagnostic Capability

(71) Applicant: TE Connectivity Solutions GmbH, Schaffhausen (CH)

(72) Inventor: Marcus PRIEST, Carpinteria, CA (US)

(73) Assignee: TE Connectivity Solutions GmbH, Schaffhausen (CH)

(21) Appl. No.: 18/764,437

(22) Filed: Jul. 5, 2024

(51) Int. Cl. H01H 1/00; G01R 31/327; H01H 1/20

(52) U.S. Cl. CPC H01H 1/0015; G01R 31/3274; H01H 1/20

(57) ABSTRACT

A power switch for use in an electrical system, a power switch electrical control system and a method of monitoring the operation of an electrical control system of a power switch. The power switch includes a housing. A controller is positioned in the housing. At least one sensor is positioned in the housing and is provided in electrical communication with the controller. The at least one sensor collects data in real time from inside the housing. The collected data is sent to the controller in real time and analyzed to determine if the operation of the power switch is within designated safety ranges.

### FIELD OF THE INVENTION

The invention relates generally to power switching devices for electric circuits, and more particularly to contactor assemblies.

### BACKGROUND OF THE INVENTION

Power switching devices, such as electromagnetic relays, contactors and/or solid-state relays are often used in electronic system. However, the power switching devices are not able to self-test critical parameters relating to their health or proper operation, which can result in the failure or improper operation of the devices and the system.

It would, therefore, be beneficial to provide a power switching device that can self-test critical parameters relating to its health or proper operation. In particular, it would be beneficial to provide a power switched device that can measure its own performance state, providing the measured data back to a system controller for the purpose of system management and reliability.

### SUMMARY OF THE INVENTION

An embodiment is directed to a power switch for use in an electrical system. The power switch includes a housing. A controller is positioned in the housing. At least one sensor is positioned in the housing and is provided in electrical communication with the controller. The at least one sensor collects data in real time from inside the housing. The collected data is sent to the controller in real time and analyzed to determine if the operation of the power switch is within designated safety ranges.

An embodiment is directed to a power switch electrical control system which includes a controller positioned inside a housing of a power switch. One or more sensors are positioned inside the housing of the power switch. The one or more sensors are provided in electrical communication with the controller. The one or more sensors collect data in real time from inside the housing of the power switch and transmit the collected data to the controller. The controller compares the collected data and stored data to determine if the collected data is within designated safety ranges. The controller may terminate the operation of the power switch if the collected data is not within the designated safety ranges.

An embodiment is directed to a method of monitoring the operation of an electrical control system of a power switch. The method includes: transmitting real time collected data back from sensors located internal to a housing of a power switch internal controller located internal to the housing of the power switch; and comparing, in real time, the collected data to data stored in the controller internal controller to determine if the collected data is within the designated safety ranges. If the collected data is outside of the designated safety ranges, the controller may terminate the operation of the power switch. If the collected data is within the designated safety ranges, the controller allows the operation of the power switch to continue.

Other features and advantages of the present invention will be apparent from the following more detailed description of the preferred embodiment, taken in conjunction with the accompanying drawings which illustrate, by way of example, the principles of the invention.

### BRIEF DESCRIPTION OF THE DRAWINGS

FIG. 1 is a view of an illustrative power switch or contactor which incorporates a controller for self-testing and self-monitoring.

FIG. 2 is a cross-sectional view of the contactor taken along line 2-2 of FIG. 1.

FIG. 3 is a block diagram of an illustrative monitoring system of the present invention.

FIG. 4 is a flow chart of a method of controlling the operation of the power switch or contactor and the electrical system.

### DETAILED DESCRIPTION OF THE INVENTION

The description of illustrative embodiments according to principles of the present invention is intended to be read in connection with the accompanying drawings, which are to be considered part of the entire written description. In the description of embodiments of the invention disclosed herein, any reference to direction or orientation is merely intended for convenience of description and is not intended in any way to limit the scope of the present invention. Relative terms such as “lower,” “upper,” “horizontal,” “vertical,” “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation unless explicitly indicated as such. Terms such as “attached,” “affixed,” “connected,” “coupled,” “interconnected,” and similar refer to a relationship wherein structures are secured or attached to one another either directly or indirectly through intervening structures, as well as both movable or rigid attachments or relationships, unless expressly described otherwise.

Moreover, the features and benefits of the invention are illustrated by reference to the preferred embodiments. Accordingly, the invention expressly should not be limited to such embodiments illustrating some possible non-limiting combination of features that may exist alone or in other combinations of features, the scope of the invention being defined by the claims appended hereto.

Provided is a power switching device or contactor assembly 100 and a method of controlling the operation of a power switching device or contactor assembly 100. Embodiments of the present disclosure, for example, in comparison to concepts failing to include one or more features disclosed herein, provide for a power switching device or contractor which can self-test critical parameters relating to its health or proper operation, and which can measure its own performance state, providing the measured data back to a system controller for the purpose of system management and reliability.

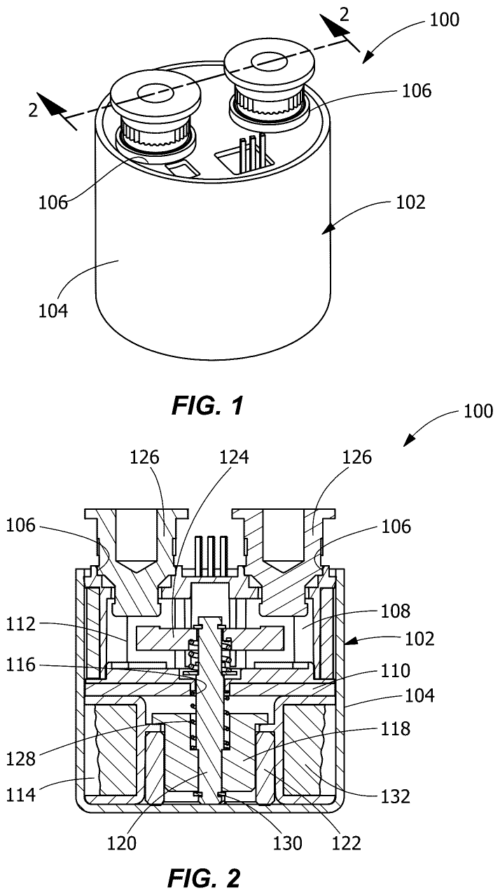

An illustrative embodiment of a contactor assembly 100 is shown in FIGS. 1 and 2. While the illustrative embodiment illustrates the contactor assembly 100, different contactor assemblies and power switched may be used.

The contactor assembly 100 includes housing 102 having a housing wall 104 including at least one aperture 106 extending through the housing wall 104. The housing wall 104 further defines a cavity 108. A partition 110 is positioned in the cavity 108 and defines at least two regions 112, 114 within the cavity 108. The partition 110 further includes a partition aperture 116 positioned to allow communication between the at least two regions 112, 114.

The contactor assembly 100 further includes an armature 118 positioned within the cavity 108. The armature 118 further includes a central bore 120. The armature 118 is slidably positioned via a bearing 122, allowing the central bore 120 to slidably extend through the partition aperture 116, along guide 123, into both of the at least two regions 112, 114. A movable electrical contact bridge 124 is attached to the central bore 120 and configured to be in selective communication with fixed electrical contacts 126 such that the central bore 120 may be selectively positioned to allow communication between the electrical contact bridge 124 and the fixed electrical contacts 126. The fixed electrical contacts 126 may be further configured to selectively communicate with an external circuit (not shown) via the at least one aperture 106.

The armature 118 further includes an armature spring 128 positioned in the region 114. The armature spring 128 is attached to both the partition 110 and armature 118. The armature spring 128 is configured to apply an armature spring force to the armature 128. The armature spring force may cause the armature 118 to slidably at least partially retract through the partition aperture 116 which may selectively position the armature 118 such that the electrical contact bridge 124 and fixed electrical contacts 126 will not be in communication. A retaining clip 130 is added to an end of the central bore 120 to transfer an impact between the armature 118 and the electrical contact bridge 124 during movement of the armature 118, in order to allow for an increased parting force and velocity.

The contactor assembly 100 further includes an electrically conductive coil 132 positioned within the housing 102 and configured to apply a magnetic force to the armature 118 in response to a coil current within the electrically conductive coil 132. The magnetic force may be in opposition to the armature spring force acting on the armature 118. The magnetic force may cause the armature 118 to slidably at least partially extend through the partition aperture 116, which may selectively position the armature 118 such that the electrical contact bridge 124 and fixed electrical contacts 126 will be in communication. The rapidity of the mechanical movement of the armature 118, in response to the magnetic force, determines how quickly the contactor assembly 100 will respond to the application of the coil current.

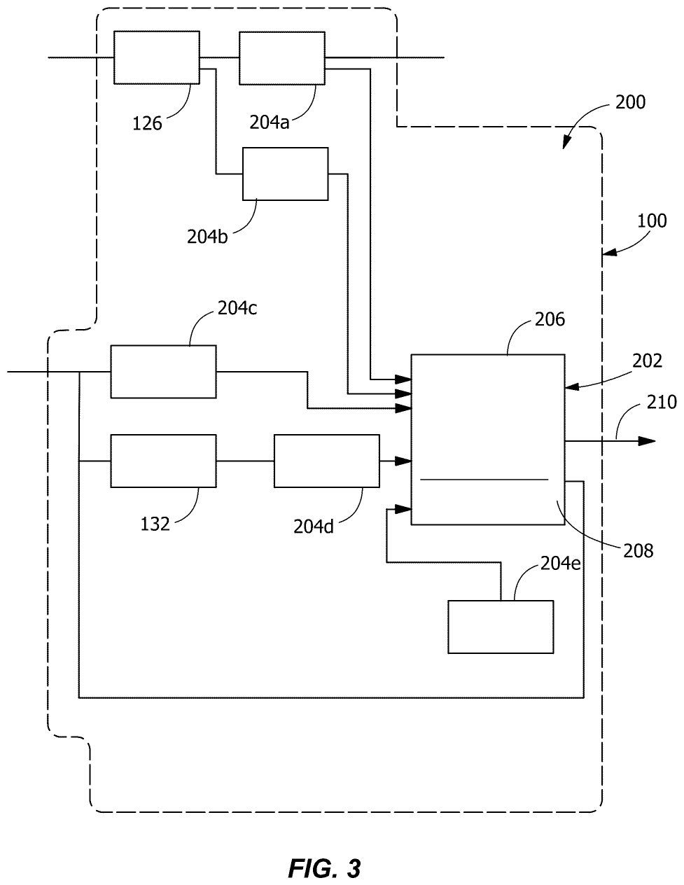

FIG. 3 is a block diagram of a representative power switch electrical control system 200 of the illustrative contactor assembly 100. While the electrical control system 200 is shown in relation to the contactor assembly 100, the electrical control system 200 may be used with other types of contactors and power switched.

The electrical control system include an internal controller 202 which is positioned inside of the housing 102 of the contactor assembly 100. The internal controller 202 may include a microcontroller 206 and a memory 208. In general, the internal controller 202 monitors status data, compiles the data, transmits the data via a communications bus, and intercedes in the operation of the contact assembly 100 for safety purposes, as will be more fully described.

As shown in FIG. 3, one or more sensors 204 are provided to monitor and collect data in real time relative to different components of the contactor assembly 100. The sensors 204 may be of different varieties to monitor different parameters of different components. For example, sensors 204 may be provided to monitor and collect data in real time regarding: i) the state of contact or junction (i.e., conduction or not); ii) state of the armature; iii) main contact or junction current; iv) contact voltage drop of forward junction drop; v) voltage on input as wall as output; vi) coil current or current voltage (and thereby, coil resistance and temperature); vii) main contact or junction temperature; viii) device motion; and/or ix) internal atmosphere (sealed device with internal gas, vacuum, etc.). Sensors 204 may also be provided to monitor and collect data for other parameters. In the illustrative embodiment shown, a load sensor 202a, a contact sensor 202b, a contactor coil current sensor 204c, a contactor coil voltage sensor 204d, and an ambient temperature sensor 204e are shown. However, different sensors may be used.

The internal controller 202 receives the data collected from the one or more sensors 204. The collected data is compiled and compared to stored data provide in the memory 208 of the internal controller 202. The stored data is data which indicates the acceptable ranges for the contactor assembly 100 to be operated safely. The collected data may also be transmitted via a communications bus 210 to outside of the housing 102 of the contactor assembly 100.

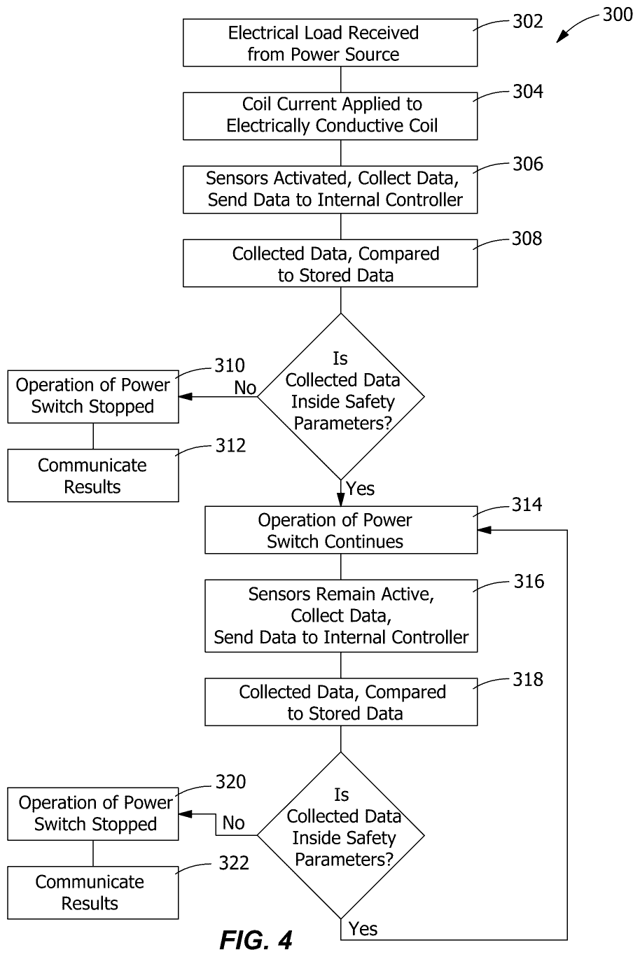

Referring to the flow chart of FIG. 4, an illustration embodiment of the operation 300 of the contactor assembly 100 having an internal controller 202 is shown. Initially, the contactor assembly 100 or power switch receives an electrical load from a power source, as represented by 302. In the illustrative embodiment, a coil current is applied to the electrically conductive coil 132, causing the central bore 120 of the armature 118 and the electrical contact bridge 124 to move toward the fixed electrical contacts 126, as represented by 304. As this occurs, the sensors 204 are activated and transmit real time collected data back to the internal controller 202, as represented by 306. Additionally, or alternatively, data collection may begin any time the source or coil bias power is active.

The internal controller 202 compares, in real time, the collected data to the stored data to determine if the operation of the contactor assembly 100 or power switch is within the designated safety ranges, as represented by 308. If the collected data is outside of the designated safety ranges, the further operation of the contactor assembly 100 or power switch may be prevented and the coil current applied to the electrically conductive coil 132 may be stopped, preventing the electrical contact bridge 124 from electrically engaging the fixed electrical contacts 126, as represented by 310. Any stoppage and/or relative data are communicated via the communication bus outside of the contactor assembly 100 or power switch, as represented by 312. If the collected data is within the designated safety ranges, the further operation of the contactor assembly 100 or power switch is allowed to continue, allowing the electrical contact bridge 124 to electrically engage the fixed electrical contacts 126, as represented by 314.

With the contactor assembly 100 supplied with source voltage or coil bias power or with the power switch operating, i.e., the electrical contact bridge 124 in electrical engagement with the fixed electrical contacts 126, the sensors 204 remain active and continue to transmit real time collected data back to the internal controller 202, as represented by 316. The internal controller 202 compares, in real time, the collected data to the stored data to determine if the operation of the contactor assembly 100 or power switch is within the designated safety ranges, as represented by 318. If any of the collected data is outside of the designated safety ranges, the further operation of the contactor assembly 100 or power switch may be stopped and the coil current applied to the electrically conductive coil 132 is stopped, causing the electrical contact bridge 124 to be removed from the fixed electrical contacts 126 preventing current from flowing across the electrical contact bridge 124, as represented by 320. The stoppage and relative data are communicated via the communication bus outside of the contactor assembly 100 or power switch, as represented by 322. If all of the collected data is within the designated safety ranges, the further operation of the contactor assembly 100 or power switch is allowed to continue, as represented by 314.

While the invention has been described with reference to a preferred embodiment, it will be understood by those skilled in the art that various changes may be made and equivalents may be substituted for elements thereof without departing from the spirit and scope of the invention as defined in the accompanying claims. One skilled in the art will appreciate that the invention may be used with many modifications of structure, arrangement, proportions, sizes, materials and components and otherwise used in the practice of the invention, which are particularly adapted to specific environments and operative requirements without departing from the principles of the present invention. The presently disclosed embodiments are therefore to be considered in all respects as illustrative and not restrictive, the scope of the invention being defined by the appended claims, and not limited to the foregoing description or embodiments.

1. A power switch for use in an electrical system, the power switch comprising
a housing;
a controller positioned in the housing;
at least one sensor positioned in the housing and provided in electrical communication with the controller, the at least one sensor collects data in real time from inside the housing;
wherein the collected data is sent to the controller in real time and analyzed to determine if the operation of the power switch is within designated safety ranges.

2. The power switch as recited in claim 1, wherein the controller is a microcontroller.

3. The power switch as recited in claim 1, wherein the controller includes a memory.

4. The power switch as recited in claim 1, wherein a communications bus extends from the controller to outside of the housing of the power switch.

5. The power switch as recited in claim 1, wherein the power switch is a contactor.

6. The power switch as recited in claim 5, wherein the contactor has fixed contacts and a movable electrical contact bridge.

7. A power switch electrical control system comprising:
a controller positioned inside a housing of a power switch;
one or more sensors positioned inside the housing of the power switch, the one or more sensors provided in electrical communication with the controller;
wherein the one or more sensors collect data in real time from inside the housing of the power switch and transmit the collected data to the controller;
wherein the controller compares the collected date and stored dated to determine if the collected date is within designated safety ranges;
wherein the controller terminated the operation of the power switch if the collected date in to within the designated safety ranges.

8. The power switch electrical control system as recited in claim 7, wherein the controller is a microcontroller.

9. The power switch electrical control system as recited in claim 7, wherein the controller includes a memory.

10. The power switch electrical control system as recited in claim 7, wherein a communications bus extends from the controller to outside of the housing of the power switch.

11. The power switch electrical control system as recited in claim 7, wherein the power switch is a contactor.

12. The power switch electrical control system as recited in claim 7, wherein the contactor has fixed contacts and a movable electrical contact bridge.

13. A method of monitoring the operation of an electrical control system of a power switch, the method including:
transmitting real time collected data back from sensors located internal to a housing of a power switch internal controller located internal to the housing of the power switch;
comparing, in real time, the collected data to data stored in the controller internal controller to determine if the collected data is within the designated safety ranges;
wherein if the collected data is outside of the designated safety ranges, the controller terminates the operation of the power switch;
wherein if the collected data is within the designated safety ranges, the controller allows the operation of the power switch to continue.

14. The method of monitoring the operation of an electrical control system of a power switch as recited in claim 13, wherein the collected data is communicated via the communication bus outside of the housing of the power switch.

15. The method of monitoring the operation of an electrical control system of a power switch as recited in claim 13, wherein if the collected data is outside of the designated safety ranges, a coil current applied to an electrically conductive coil of the power switch is stopped.

16. The method of monitoring the operation of an electrical control system of a power switch as recited in claim 15, wherein the internal controller continues to compare, in real time, the collected data to the stored data to determine if the collected data is outside of the designated safety ranges, wherein if the collected data is outside of the designated safety ranges, the controller terminates the operation of the power switch.

17. The method of monitoring the operation of an electrical control system of a power switch as recited in claim 15, wherein the internal controller is a microcontroller.

18. The method of monitoring the operation of an electrical control system of a power switch as recited in claim 15, wherein the internal controller includes a memory.

19. The method of monitoring the operation of an electrical control system of a power switch as recited in claim 15, wherein the power switch is a contactor.

20. The method of monitoring the operation of an electrical control system of a power switch as recited in claim 19, wherein the contactor has fixed contacts and a movable electrical contact bridge, wherein if the collected data is outside of the designated safety ranges, a coil current applied to an electrically conductive coil of the power switch is stopped to prevent the mating of the movable electrical contact bridge with the fixed contacts.
